(19) United States
(12) Patent Application Publication
(10) Pub. No.: US 2025/0081857 A1
(43) Pub. Date: Mar. 6, 2025

(54) SPIN ORBIT TORQUE MAGNETORESISTIVE RANDOM ACCESS MEMORY

(71) Applicant: National Tsing Hua University, Hsinchu City (TW)

(72) Inventors: Chih-Huang Lai, Hsinchu City (TW); Tsung-Yu Pan, Hsinchu City (TW); Chih-Hsiang Tseng, Hsinchu City (TW); Yi-Cheng Tsou, Hsinchu City (TW); Yu-Shen Yen, Hsinchu City (TW); Rong-Zhi Chen, Hsinchu City (TW)

(73) Assignee: National Tsing Hua University, Hsinchu City (TW)

(21) Appl. No.: 18/510,686

(22) Filed: Nov. 16, 2023

(30) Foreign Application Priority Data
Aug. 31, 2023 (TW) 112132936

(51) Int. Cl. H10N 50/85; C22C 19/00; C22C 27/04; H01F 10/32; H10B 61/00; H10N 50/20

(52) U.S. Cl. CPC H10N 50/85; C22C 19/00; C22C 27/04; H01F 10/329; H10B 61/00; H10N 50/20

(57) ABSTRACT

A spin orbit torque magnetoresistive random access memory (SOT MRAM) includes at least a spin current source alloy layer, a ferromagnetic free layer, and an insulation layer. The spin current source alloy layer is a nickel-tungsten alloy layer. The ferromagnetic free layer is located on the spin current source alloy layer. The insulation layer is located on the ferromagnetic free layer. Since the nickel-tungsten alloy layer has favorable perpendicular magnetic anisotropic and can maintain a high spin Hall angle, it is suitable as a spin current source for the SOT MRAM.

### CROSS-REFERENCE TO RELATED APPLICATION

This application claims the priority benefit of Taiwan application serial no. 112132936, filed on Aug. 31, 2023. The entirety of the above-mentioned patent application is hereby incorporated by reference herein and made a part of this specification.

### BACKGROUND

### Technical Field

The disclosure relates to a magnetoresistive random access memory technology, and in particular, to a spin orbit torque magnetoresistive random access memory (SOT MRAM).

### Description of Related Art

With the development of artificial intelligence, electric vehicles, and big data, the demand for memory is gradually increasing. Since current mainstream memories such as DRAM and SRAM are volatile memories and must be continuously powered to retain data, excessive energy is consumed in data storage.

In order to reduce energy consumption, non-volatile memories such as MRAM and RRAM are gradually receiving attention. In the development of MRAM, it can be mainly divided into three generations based on different writing methods: writing using magnetic field, writing using spin transfer torque (STT), and writing using spin orbit torque (SOT).

In the third generation of SOT MRAM, heavy metal materials are usually used as the source of spin current to achieve a favorable spin Hall effect. However, since the crystal structure of ferromagnetic materials in MRAM is mostly body-centered cubic (BCC), it is difficult for existing heavy metal materials to match it. As a result, the spin Hall effect is not significant and the write current cannot be reduced.

### SUMMARY

The disclosure provides a spin orbit torque magnetoresistive random access memory, which can increase the spin Hall angle and thereby reduce the write current.

The spin orbit torque magnetoresistive random access memory of the disclosure at least includes a spin current source alloy layer, a ferromagnetic free layer, and an insulation layer. The spin current source alloy layer is a nickel-tungsten alloy layer. The ferromagnetic free layer is located on the spin current source alloy layer. The insulation layer is located on the ferromagnetic free layer.

In an embodiment of the disclosure, the nickel-tungsten alloy layer is in direct contact with the ferromagnetic free layer.

In an embodiment of the disclosure, the nickel-tungsten alloy layer contains 30 at % or more of tungsten.

In an embodiment of the disclosure, the nickel-tungsten alloy layer contains 90 at % or less of tungsten.

In an embodiment of the disclosure, the nickel-tungsten alloy layer has a plurality of regions with different polarities.

In an embodiment of the disclosure, the shapes of the plurality of regions include block shapes, linear shapes, or a combination thereof.

In an embodiment of the disclosure, each of the plurality of regions has a different composition ratio of nickel and tungsten.

In an embodiment of the disclosure, the nickel-tungsten alloy layer is a multi-layer film structure. The multi-layer film structure consists of a plurality of sub-layers. By controlling the different composition ratio of nickel and tungsten in each sub-layer, the switching behavior of the ferromagnetic layer can be controlled.

In an embodiment of the disclosure, the number of film layers in the multi-layer film structure can be from 2 to 10 layers.

Based on the above, the disclosure uses a nickel-tungsten alloy capable of matching the ferromagnetic free layer structure as a spin current source to increase the spin Hall angle and reduce the write current. Moreover, by adjusting the alloy ratio of different regions in the nickel-tungsten alloy layer, the properties of the device can be adjusted, such as the spin Hall angle switching polarity. Therefore, the spin orbit torque magnetoresistive random access memory of the disclosure can be applied more extensively.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1 is a schematic cross-sectional diagram of a spin orbit torque magnetoresistive random access memory according to an embodiment of the disclosure.

FIG. 2 is a schematic three-dimensional diagram of a spin orbit torque magnetoresistive random access memory according to another embodiment of the disclosure.

FIG. 3 is an X-ray diffraction pattern of a nickel-tungsten alloy layer of Preparation Examples 1 to 5.

FIG. 4 is an image of a magnetic moment switching observed in Experimental Example 4 using the magneto-optical Kerr effect.

FIG. 5 is a switching current density diagram of a spin orbit torque magnetoresistive random access memory of Experimental Examples 1 to 5.

FIG. 6A is a SOT switching curve diagram of Experimental Example 2.

FIG. 6B is a SOT switching curve diagram of Experimental Example 4.

### DESCRIPTION OF THE EMBODIMENTS

The following content provides various embodiments for implementing different features of the disclosure. However, the embodiments are only examples and are not intended to limit the scope and application of the disclosure.

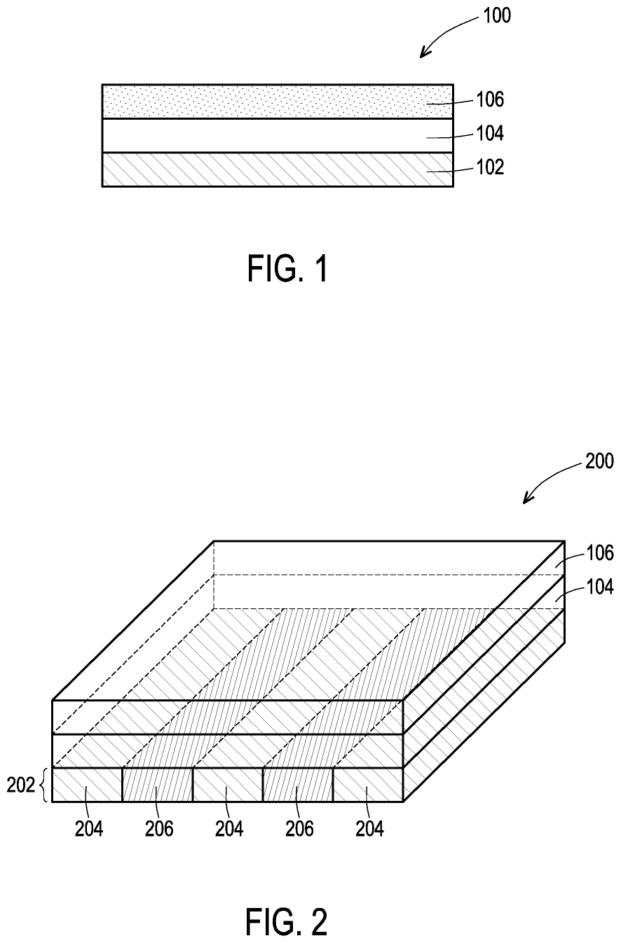

FIG. 1 is a schematic cross-sectional diagram of a spin orbit torque magnetoresistive random access memory according to an embodiment of the disclosure.

Referring to FIG. 1, a spin orbit torque magnetoresistive random access memory 100 of the embodiment at least includes a spin current source alloy layer 102, a ferromagnetic free layer 104, and an insulation layer 106. The spin current source alloy layer 102 is a nickel-tungsten alloy layer. The “nickel-tungsten alloy layer” in the description refers to an alloy consisting of nickel and tungsten. The nickel and tungsten are the main components, and the rest are unavoidable impurities. In an embodiment, the tungsten content of the nickel-tungsten alloy layer ranges from 1 at % to 99 at %. From the perspective of increasing the spin Hall angle, the nickel-tungsten alloy layer can contain 30 at % or more of tungsten, such as 50 at % or more of tungsten or 70 at % or more of tungsten; and the rest is nickel. In an embodiment, the nickel-tungsten alloy layer can contain less than 90 at % or less of tungsten. As for the thickness of the spin current source alloy layer 102, the thickness of the spin current source alloy layer 102 can be 4 nm or more, such as 10 nm or more, and in consideration of the electrical properties and structural strength, the thickness of the spin current source alloy layer 102 can be up to several hundred nanometers, without affecting the spin Hall angle.

The spin current source alloy layer 102 can be formed by, for example, but not limited to, sputtering to form a nickel-tungsten alloy layer on a substrate (not shown). In an embodiment, the target material used for sputtering is a nickel-tungsten alloy target. In another embodiment, the sputtering is co-sputtering using a nickel target and a tungsten target, and by regulating the coating power of the nickel target and the coating power of the tungsten target, nickel-tungsten alloys with different composition ratios of nickel and tungsten can be formed.

Continuing to refer to FIG. 1, the ferromagnetic free layer 104 is located on the spin current source alloy layer 102. The material of the ferromagnetic free layer 104 includes metal or metal alloy, for example, but not limited to Fe, Co, Ni, Ir, B, Bi, Pt, Pd, Ta, Tb, Mo, Cu, Pt, W, or alloys of two or three of the aforementioned metals, such as FeB, CoFe, FePt, FePd, CoPt, CoPd, CoNi, CoFeB, or TbFeCo. In FIG. 1, the spin current source alloy layer 102 is in direct contact with the ferromagnetic free layer 104, which can optimize the effect of reducing the write current. However, the disclosure is not limited thereto; in other embodiments, other functional film layers can be disposed between the spin current source alloy layer 102 and the ferromagnetic free layer 104, which can still have the effect of reducing the write current.

The ferromagnetic free layer 104 can be formed by, for example, but not limited to, sputtering, physical vapor deposition (PVD), or chemical vapor deposition (CVD) such as high-density chemical vapor deposition (HDP CVD), low-pressure chemical vapor deposition (LPCVD) or plasma-enhanced chemical vapor deposition (PECVD) applicable to the disclosure.

Referring to FIG. 1 again, the insulation layer 106 is located on the ferromagnetic free layer 104. The insulation layer 106 can be a metal oxide or other insulation materials suitable as tunneling barriers, for example, magnesium oxide, aluminum oxide, titanium oxide, or a combination thereof. The insulation layer 106 can be formed by, for example, but not limited to, sputtering, physical vapor deposition, or chemical vapor deposition such as high-density chemical vapor deposition, low-pressure chemical vapor deposition, or plasma-enhanced chemical vapor deposition applicable to the disclosure.

In another embodiment, the spin current source alloy layer 102 (nickel-tungsten alloy layer) is a multi-layer film structure. The multi-layer film structure consists of a plurality of sub-layers (not shown), such as 2 to 10 layers. By controlling the difference in the composition ratio of nickel and tungsten in each sub-layer, the switching behavior of the ferromagnetic free layer 104 can be controlled. The multi-layer film structure is formed by, for example, but not limited to, sputtering to form the sub-layers layer by layer, and by regulating the coating power of the nickel target and the coating power of the tungsten target, the composition ratio of nickel and tungsten in each sub-layer can be changed.

FIG. 2 is a schematic three-dimensional diagram of a spin orbit torque magnetoresistive random access memory according to another embodiment of the disclosure, wherein the same or similar parts and components are denoted by the same reference numerals as those in the previous embodiment, and the relevant content of the same or similar parts and components can be found in the descriptions of the previous embodiment and will not be repeated here.

Referring to FIG. 2, the difference between the embodiment and the previous embodiment is that the nickel-tungsten alloy layer has a plurality of regions with different polarities. Referring to FIG. 2, a spin current source alloy layer 202 in a spin orbit torque magnetoresistive random access memory 200 has a first region 204 and a second region 206 with different polarities. The first region 204 and the second region 206 are both nickel-tungsten alloy layers, but each has a different composition ratio of nickel and tungsten. It has been verified by experiments of the disclosure that different composition ratios of nickel and tungsten have different switching polarities, which will be described in details below.

Although the first region 204 and the second region 206 of FIG. 2 are strip-shaped, the disclosure is not limited thereto. The shapes of the first region 204 and the second region 206 can also include block shapes, linear shapes, or a combination thereof. The spin current source alloy layer 202 is formed by, for example, but not limited to, separately plating the first region 204 and the second region 206 with nickel-tungsten alloys of different compositions using a photomask process to achieve different results in the composition ratios of nickel and tungsten in different regions. For example, a mask layer (not shown) is first formed on a substrate (not shown), and then the mask layer is patterned using a first photomask process to expose the substrate in the first region 204. Then, a nickel-tungsten alloy with a first composition ratio is plated. The mask layer is then removed, and then the steps of forming another mask layer (not shown) and performing a second photomask process are repeated to cover the first region 204 with the patterned mask layer and expose the substrate in the second region 206. Then, a nickel-tungsten alloy with a second composition ratio is plated to form the spin current source alloy layer 202 having the first region 204 and the second region 206 with different composition ratios of nickel and tungsten.

The following experiments are given to verify the implementation effect of the disclosure, but the disclosure is not limited to the following content.

### Preparation Examples 1 to 5

A nickel-tungsten alloy layer was formed on a silicon substrate (with a thickness of approximately 675 μm) using a DC magnetron sputtering machine with a nickel target and a tungsten target for co-sputtering. There was a 200 nm thermal oxide layer (SiO₂) on the surface of the silicon substrate. Table 1 below shows different preparation examples and the corresponding coating power ratios thereof.

TABLE 1

| Preparation | Power ratio of nickel | Nickel-tungsten |
|---|---|---|
| example | target to tungsten target | alloy |
| 1 | 100:15.7 | Ni₉₀W₁₀ |
| 2 | 50:30.2 | Ni₇₀W₃₀ |
| 3 | 50:71 | Ni₅₀W₅₀ |
| 4 | 25:83.25 | Ni₃₀W₇₀ |
| 5 | 8:100 | Ni₁₀W₉₀ |

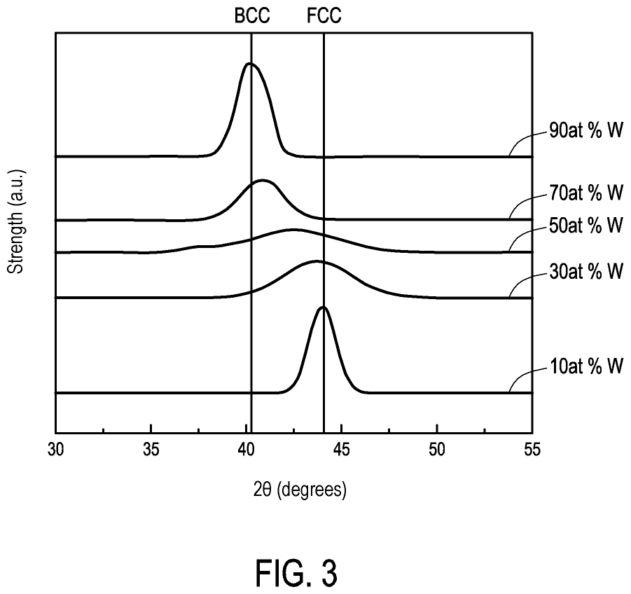

Then, X-ray diffraction was used to conduct structural analysis separately on the nickel-tungsten alloy layers of Preparation Examples 1 to 5, and FIG. 3 was obtained.

It could be seen from FIG. 3 that the peak positions of Ni₉₀W₁₀ (10at % W) and Ni₁₀W₉₀ (90at % W) were very different and corresponded to two textures FCC and BCC, respectively.

### Experimental Example 1

In order to test the element characteristics, a first titanium layer (with a thickness of approximately 2 nm) was firstly deposited on a silicon substrate (1 cm×1 cm) with an oxidized surface using a DC magnetron sputtering machine. Then, a nickel-tungsten alloy layer (with a thickness of approximately 6 nm) was formed in the same manner as in Preparation Example 1. Then, a cobalt layer as a ferromagnetic free layer (with a thickness of approximately 2 nm), a magnesium oxide layer (with a thickness of approximately 2 nm) as an insulation layer, and a second titanium layer (with a thickness of approximately 4 nm) were sequentially formed on the nickel-tungsten alloy layer using the DC magnetron sputtering machine. The first titanium layer could increase the adsorption between the structure and the silicon dioxide on the surface of the silicon substrate, and the second titanium layer could prevent the oxidation of the structure. After the vacuum degree reached 4×10⁻⁷ mTorr or lower, each of the above layers was deposited in an argon atmosphere of 3 mTorr.

After the film deposition was completed, the above stacked film was made into a Hall cross element with a width of 20 μm and a length of 90 μm using yellow photolithography process and electronic etching technology to measure the spin current generated by spin electrons.

### Experimental Examples 2 to 4

The Hall cross element was produced in the same manner as Experimental Example 1, but when forming the nickel-tungsten alloy layer, the manner of Preparation Examples 2 to 4 was used instead, and the Hall Cross elements of Experimental Examples 2 to 4 were obtained accordingly.

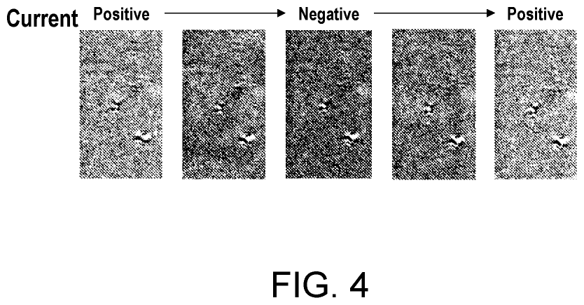

Then, the element of Experimental Example 4 (the nickel-tungsten alloy layer beingNi₃₀W₇₀) was placed under a magneto-optical Kerr microscope to observe the switching of the magnetic moment thereof. During the measurement process, a current was passed through the current axis of the Hall cross element, and the magnetic moment of the ferromagnetic free layer above was switched using a spin polarized current generated. Due to the Kerr magneto-optical effect, when the magnetic moment was switched, the image seen under the magneto-optical Kerr microscope would change in light and dark, as shown in FIG. 4.

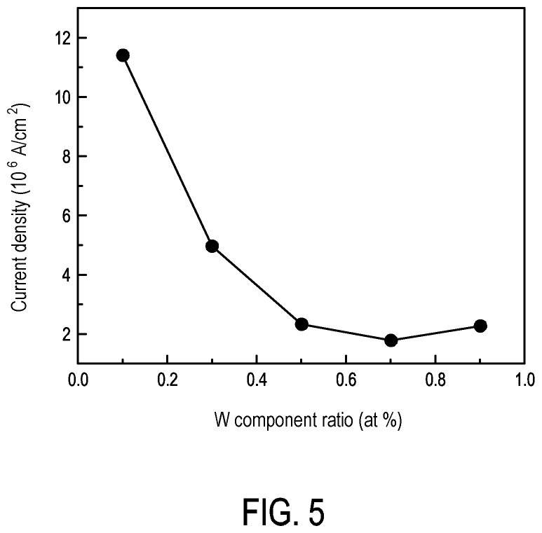

It could be seen from FIG. 4 that when the switching was performed, the image slowly turned from white on the far left to black, which meant that the magnetic moment was switched from top to bottom. When the current direction was opposite, the magnetic moment would switch from bottom to top, and the image would slowly return from black in the middle to white, whereby the minimum critical current density (Jc) required for the spin current to switch the magnetic moment could be calculated. According to the above method, the critical switching current densities of the elements of Experimental Examples 1 to 5 were separately detected, and FIG. 5 could be obtained.

It could be seen from FIG. 5 that different composition ratios of the nickel-tungsten alloy layer would have different critical switching current densities. For example, the element of Experimental Example 4 (the W component ratio in the tungsten alloy layer being 0.7) had the smallest critical switching current density, which was approximately 1.8×10⁶ A/cm², and could achieve a lower write current than the currently used beta-W and was more flexible in terms of process conditions, thereby showing that the nickel-tungsten alloy layer of the disclosure had a great competitive advantage as a spin current source material.

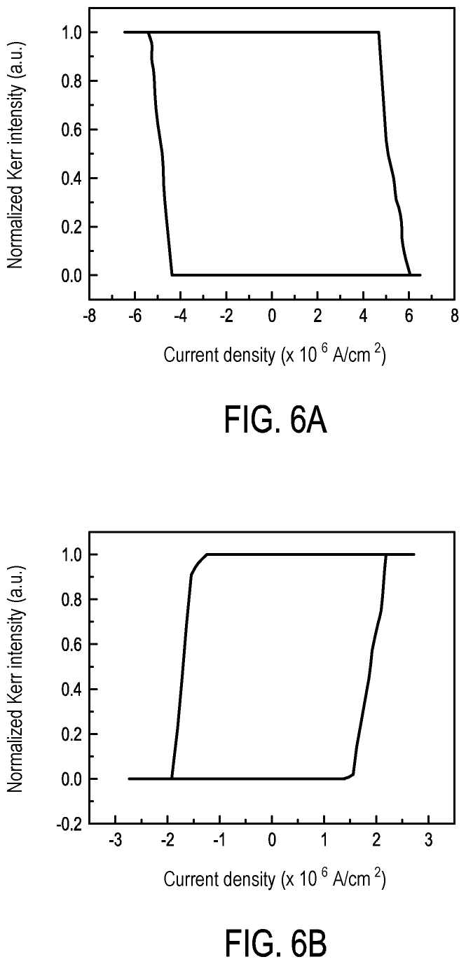

In addition to the switching current, FIG. 6A and FIG. 6B could be obtained by further plotting the light intensity received by the magneto-optical Kerr microscope against the current density passing through the current axis. FIG. 6A is a SOT switching diagram of Experimental Example 2 (the nickel-tungsten alloy layer being Ni₇₀W₃₀), and FIG. 6B is a SOT switching diagram of Experimental Example 4 (the nickel-tungsten alloy layer being Ni₃₀W₇₀).

It could be seen from FIG. 6A and FIG. 6B that the switching curve in Experimental Example 2 was clockwise, while the switching curve in Experimental Example 4 was counterclockwise. Therefore, it was verified that the different composition ratios of nickel and tungsten mentioned above would have different switching polarities. It was estimated that the amount of W would directly affect the crystal structure of the element, thereby resulting in different switching properties.

To sum up, the disclosure uses the nickel-tungsten alloy as a spin electronic material to replace the single heavy metal layer that is currently common. The nickel-tungsten alloy is highly elastic and compatible in the MRAM process, and has a spin Hall angle comparable to tungsten metal. In addition, the disclosure can also change the properties of the element by adjusting the alloy ratio of the nickel-tungsten alloy layer, such as the spin Hall angle switching polarity, so there is an additional variable condition in practical applications.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure shall be defined in the appended claims.

What is claimed is:

1. A spin orbit torque magnetoresistive random access memory, comprising:
a spin current source alloy layer, wherein the spin current source alloy layer is a nickel-tungsten alloy layer;
a ferromagnetic free layer, located on the spin current source alloy layer; and
an insulation layer, located on the ferromagnetic free layer.

2. The spin orbit torque magnetoresistive random access memory according to claim 1, wherein the nickel-tungsten alloy layer is in direct contact with the ferromagnetic free layer.

3. The spin orbit torque magnetoresistive random access memory according to claim 1, wherein the nickel-tungsten alloy layer contains 30 at % or more of tungsten.

4. The spin orbit torque magnetoresistive random access memory according to claim 1, wherein the nickel-tungsten alloy layer contains less than 90 at % or less of tungsten.

5. The spin orbit torque magnetoresistive random access memory according to claim 1, wherein the nickel-tungsten alloy layer has a plurality of regions with different polarities.

6. The spin orbit torque magnetoresistive random access memory according to claim 5, wherein shapes of the plurality of regions comprise block shapes, linear shapes, or a combination thereof.

7. The spin orbit torque magnetoresistive random access memory according to claim 5, wherein each of the plurality of regions has a different composition ratio of nickel and tungsten.

8. The spin orbit torque magnetoresistive random access memory according to claim 1, wherein the nickel-tungsten alloy layer is a multi-layer film structure, the multi-layer film structure consists of a plurality of sub-layers, and a switching behavior of the ferromagnetic free layer is controlled by controlling a different composition ratio of nickel and tungsten in each of the sub-layers.

9. The spin orbit torque magnetoresistive random access memory according to claim 8, wherein a number of film layers in the multi-layer film structure is 2 to 10 layers.
